(19) United States
(12) Patent Application Publication
(10) Pub. No.: US 2001/0028111 A1
(43) Pub. Date: Oct. 11, 2001

(54) Contact device and method of manufacturing the same

(75) Inventors: Etsuji Suzuki, Kanagawa (JP); Shigeo Ikeda, Kanagawa (JP)

Correspondence Address: Finnegan, Henderson, Farabow,, Garrett & Dunner, L.L.P., 1300 I Street, N.W., Washington, DC, 20005-3315, US

(73) Assignee: Yamaichi Electronics Co., Ltd.

(21) Appl. No.: 09/834,652

(22) Filed: Apr. 16, 2001

(30) Foreign Application Priority Data
Apr. 7, 2000 (JP) 2000-115677

(51) Int. Cl. H01L 21/66; G01R 31/26; H01L 21/50; H01L 23/48; H01L 23/58

(52) U.S. Cl. 257/738; 438/18; 438/117; 438/612; 257/48; 257/737

(57) ABSTRACT

A contact device of the present invention is able to contact with a spherical test terminal. The contact device has a spring and a contact part. Also, the contact part has one end on which two or more protruded portions are formed and the other end on which a top end of the sprig is attached. The protruded portions are able to contact with a spherical surface of the spherical test terminal except for the top thereof with a high degree of precision and a high degree of the contact reliability.

This application is based on Patent Application No. 2000-115677 filed Apr. 17, 2000 in Japan, the content of which is incorporated hereinto by reference.

### BACKGROUND OF THE INVENTION

1. Field of the Invention

The present invention is related to a contact device that is able to contact a test terminal of a spherical type and a method of manufacturing such a contact device.

2. Description of the Prior Art

The desire to improve the high-frequency characteristics of electronic devices is growing in recent years, in addition to the desire to shrink the size thereof. Simultaneously, the use of semiconductor devices of BGA (ball grid array) package and CSP (chip size/scale package) is also extensively increasing. In the BGA package and CSP, soldering balls are generally used as external connecting terminals connected to outside circuit substrates. In general, a number of the soldering balls are arranged in the same plane on the bottom surface of the semiconductor device. For connecting the semiconductor device with the outside circuit substrate, the soldering ball is melted to be used as an external connecting terminal. In this case, it is important that the soldering balls are the same height with respect to one another.

Regarding the semiconductor device, on the other hand, there is a need to conduct the evaluations of its performance and reliability. For uniformly obtaining the heights of the soldering balls, there is a need to make a design to prevent the soldering ball (especially the top thereof) from any scratch or stress to be caused by coming into contact with the contact device.

Conventionally, a contact device 31 made of Ni shown in FIG. 6 and a contact device designed as a structure of sandwiching a soldering ball 41 from both sides are proceeding toward practical utilization. Also, the contact device 31 shown in the figure is attached on a flexible sheet 32. The contact device 31 has a ring portion 31A as a ridge thereof. Therefore, ring portion 31A is able to contact with a spherical surface of the soldering ball 41, forming a contacted area into a ring (circular) shape.

By the way, the conventional contact device 31 shown in FIG. 6 does not have its own elastic property. Thus, an anisotropic conductive rubber is provided as a means for elastically pressing the contact device 31 to the soldering ball 41. In this case, however, it leads to anxiety about the reliability of the contact of the contact device 31 with the soldering ball 41.

For contacting a plurality of contact devices with the corresponding soldering balls at a time with a high degree of reliability, it is desirable that the contact devices are elastically deformed independently from one another, In this case, the amount of elastic deformation of the contact device should be in the rage of approximately 0.2 mm to 0.3 mm, which may be depended on the degree of accuracy in the measurement using a conventional testing device. For stabilizing its electric resistance at the time of being compressed, by the way, anisotropic conductive rubber mentioned above cannot be thickened enough to provide the above appropriate amount of the elastic deformation. Consequently, the amount of elastic deformation of the contact device using such a rubber becomes too small, for example in the rage of approximately 0.1 mm to 0.2 mm.

Accordingly, the conventional contact device has the disadvantage of decrease in the degree of its contact reliability.

### SUMMARY OF THE INVENTION

Therefore, an object of the present invention is to provide a contact device having a high degree of its contact reliability and a method of manufacturing such a contact device.

In a first aspect of the present invention, there is provided a contact device that is able to contact with a test terminal of a spherical type, comprising;

a spring; and

a contact part having one end on which two or more protruded portions are formed and the other end on which a top end of the sprig is attached, wherein

the protruded portions are able to contact with a spherical surface of the test terminal except for the top thereof.

In a second aspect of the present invention, there is provided a method of making a contact device that is able to contact with a test terminal of a spherical type, comprising the steps of:

forming a contact part integrally with two or more protruded portions on one end of the contact part by means of plating, wherein the protruded portions are arranged so as to be able to contact with a spherical surface of the test terminal except for the top thereof; and

attaching the other end of the contact part with one end of a spring.

Therefore, the present invention provides several benefits not present in the existing prior-art contact device and its manufacturing method, some of examples of which will now be given.

First, the contact device of the present invention comprises a spring and a contact part. The contact part has one end portion on which two or more protruded portions are formed and the other end portion on which a top end of the sprig is attached, so that the protruded portions are able to contact with a spherical surface of a spherical type test terminal except for the top thereof. Therefore, a plurality of the protruded portions can be simultaneously contacted with the spherical surface of the spherical type test terminal with elastic deformations of the springs, so that the degree of contact reliability can be increased.

Secondary, the method of manufacturing a contact device in accordance with the present invention makes a contact part integrally with two or more protruded portions on one end portion of the contact part by means of plating. Thus, the contact part can be manufactured with a high degree of precision, In this case, the contact part is formed on a plating plate by means of plating and then the spring is attached on the contact part on the plating plate, followed by separating a combination of the contact part and the spring from the plating plate. Therefore, the contact plate and the spring can be attached with a high degree of precision and thus resulting contact device can be of a high degree of the contact reliability never before possible.

The above and other objects, effects, features, and advantages of the present invention will become more apparent from the following description of embodiments, therefore taken in conjunction with the accompany drawings.

### BRIEF DESCRIPTION OF THE DRAWINGS

FIG. 1 is a cross sectional diagram that illustrates a main part of a testing device having a contact device in accordance with the present invention;

FIG. 2 is a schematic diagram that illustrates the condition of using the contact device shown in FIG. 1;

FIG. 3 is a perspective diagram that illustrates the contact device shown in FIG. 1 in an inverted position;

FIG. 4 is an explanation diagram that illustrates the relationship between the contact device and the soldering ball;

FIG. 5A, FIG. 5B, FIG. 5C, FIG. 5D, FIG. 5E, and FIG. 5F are explanation diagrams that illustrate the steps in the method of manufacturing the contact device of the present invention, respectively; and

FIG. 6 is a cross sectional diagram of the conventional contact device.

### DETAILED DESCRIPTION OF THE PREFERRED EMBODIMENTS

In the following description, preferred embodiments of the present invention will be explained in detail with reference to the attached drawings.

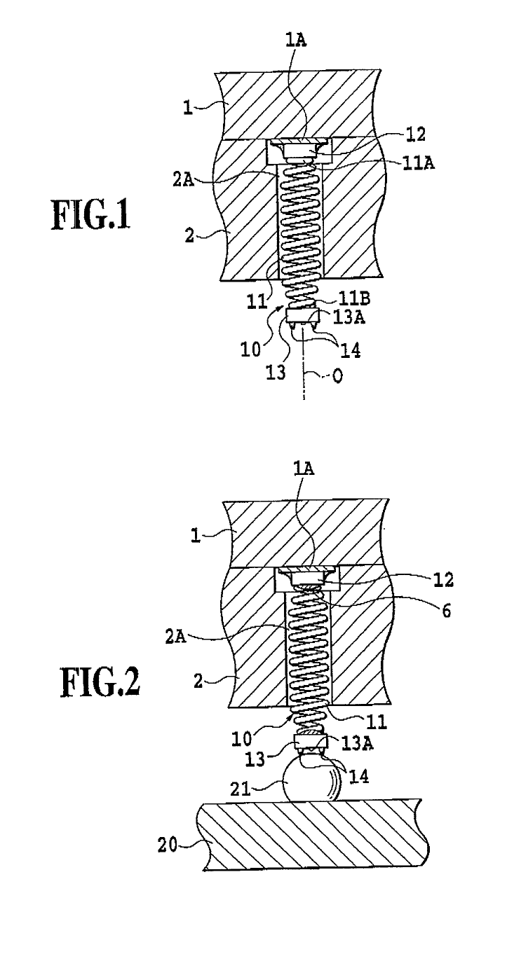

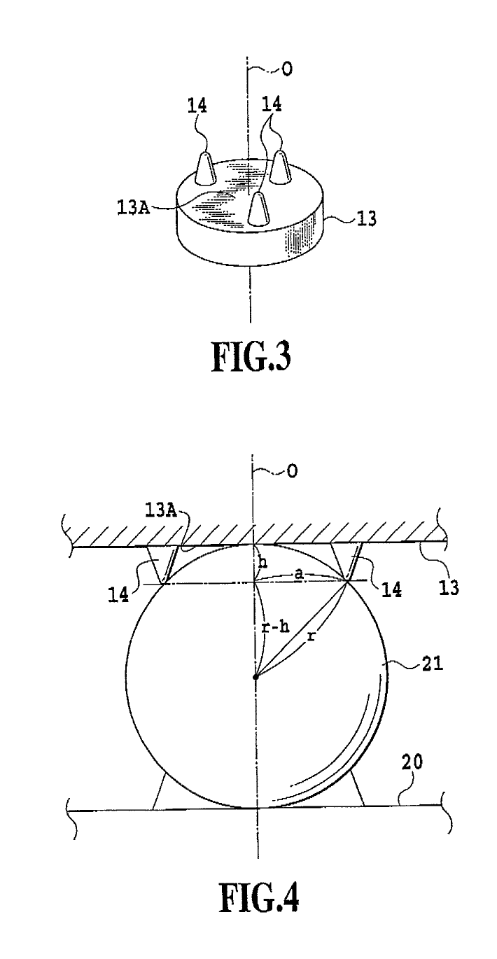

FIG. 1 is a cross sectional diagram that illustrates a main part of a testing device having a contact device 10 as a first preferred embodiment of the present invention. As shown in the figure, the contact device 10 is mounted on the surface of a substrate 1 in a testing device. The contact device 10 comprises a spring 11 made of a coil of wire (i.e., a coil spring). The coil spring 11 consists two end and a middle portion between the ends. One end (i.e., a proximal end) 11A of the spring 11 is connected to a connecting terminal 12 that is mechanically and electrically connected to an electrode 1A placed on the substrate 1 by means of plating or the like. The middle portion of the coil spring 11 is placed in a guide hole 2A opened through a spring-guide plate 2 layered on the substrate 1 of the testing device so that a spring axis “O” of the spring coil 11 is perpendicular to the surface of the substrate 1. The other end (i.e., a distal end) 11B of the coil spring 11 protrudes through the surface of the spring-guide plate 2 and is attached to a contact part 13. Furthermore, as shown in the figure, both ends 11A, 11B of the coil spring 11 have their respective diameters smaller than that of the middle portion. The distal end surface of the contact part 13 includes one end surface with a center area 13A having its center axis coincident with an extending line of the spring axis “O”. In this embodiment, three protruded conical portions 14 are formed around the center area 13A so as to be placed on a circular line at regular intervals on the plane, concentrically with the spring axis “O”.

FIG. 2 is an explanation diagram that illustrates the condition of testing a semiconductor device 20 as a testing object by a testing device. The testing device has the contact device 10 constructed as described above. In this case, the semiconductor device 20 has a soldering ball 21 as an external connecting terminal to be connected to the outside circuit (not shown), which is provided as a test terminal. The testing device is able to obtain any data for estimating the characteristics and reliability of the semiconductor device 20 by contacting the protruded portions 14 of the contact device 10 to the soldering ball 21. There are three protruded portions 14 provided on the same circular line, so that these protruded portions 14 can be contact with a spherical surface of the soldering ball 21 except for the top thereof, keeping in balance by elastic deformation of the coil spring 11. At this time, a tip of each of the protruded portions 14 penetrates through a film of oxide on the surface of the soldering ball 21, so that they are surely connected with one another. In addition, the protruded portions 14 are arranged on the spherical surface of the soldering ball 21 in balance, so that the pressure that makes a depression in such a surface can be restricted in a minimum amount.

Furthermore, the height of the protruded portion 14 is defined to make a space between the center area 13A of the contact part 13 and the top of the soldering ball 21. In other words, it is defined to prevent them from the contact. As a result, it prevents the soldering boll 21 from occurring deformation, so that a uniformity of the height of the soldering ball 21 can be ensured.

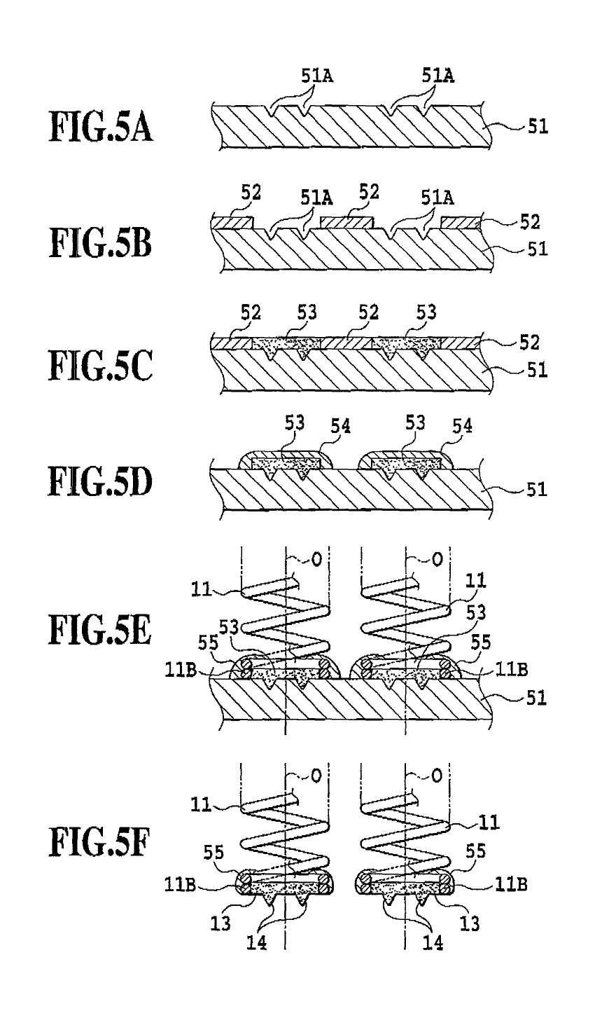

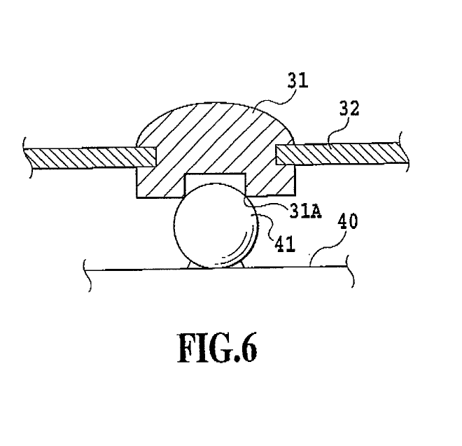

FIG. 4 is an explanation diagram that illustrates the condition in which the height “h” of the protruded portion 14 is defined so that the center area 13A of the contact part 13 and the top of the soldering ball 21 are brought into contact with one another. In the figure, the alphabet “r” represents a radius of the soldering ball 21, “a” represents the shortest distance from the spring axis “O” to the tip of the protruded portion 14 (i.e., a line segment “a” is perpendicular to the spring axis “O”). Thus, if the height “h” of the protruded portion 14 is defined by the following equation (1), then the center area 13A of the contact part 13 and the top of the soldering ball 21 are contacted with one another.

h=r[1−{1−(a/r)²}^{1/2}] (1)

For preventing the center area 13A of the contact part 13 and the top of the soldering ball 21 from occurring the contact between them, the height “h” of the protruded portion 14 must be larger than that of being defined by the above equation (1). Therefore, the desired height “h” of the protruded portion 14 can be defined by the following inequality (2).

h>r[1−{1−(a/r)²}^{1/2}] (2)

Regarding the contact device 10 contacting with the soldering ball 14, the coil spring 11 is most responsible for providing the contact device 10 with a desired elastic force.

For that reason, the pressure to be applied on the soldering ball 21 by the tip of the protruded portion 14 and the deformation amount of the contact device 10 can be optionally determined based on the selection of coil spring 11. In addition, both ends 11A, 11B of the coil spring 11 of the present embodiment have diameters smaller than that of the middle portion. Therefore, the contact terminal 12, the electrode 1A, and the contact part 13 can be downsized in addition to allow the high-dense arrangement of these components. Thereby, it is able to cope with the arrangement of soldering balls 21 with a smaller pitch.

FIGS. 5A to 5F are explanation diagrams that illustrate the respective steps of a method of molding the contact part 13 of the contact device 10.

As shown in FIG. 5A, at first, a plating plate 51 having recessed portions 51A that correspond to the respective protruded portions 14 is prepared. The plating plate 51 may be selected from, for example a SUS plate, an Al plate, or Cu plate, on which a thin plating coat is applied.

As shown in FIG. 5B, a predetermined photoresist pattern 52 is formed on the plating plate 51. In this case, a portion (a non-photoresisting portion), where no photoresist pattern 52 is present, is provide as one on which the contact part 13 will be formed.

As shown in FIG. 5C, furthermore, the plating plate 51 is subjected to a Ni-plating to grow a Ni-plating portion 63 on the non-photoresisting portion. The Ni-plating portion 53 will be provided as the contact part 13 having protruded portions 14.

After the above steps, as shown in FIG. 5D, the photoresist pattern 52 is removed, and then a soldering past 64 is applied on the plating portion 53 by means of printing or the like. Then, the tip end 11B of the coil spring 11 is placed on the plating portion 53 and then connected them together by a solder 55.

Subsequently, as shown in FIG. 5F, the plating portion 53 is peeled from the plating plate 51. Then, an integrated combination of the protrusions 14 and the contact part 13 are formed using such a plating portion 53. Before and after the formation of such a contact part 13, the contact device 10 is constructed by connecting a contact terminal 12 with the proximal end 11A of the coil spring 11, According to the present embodiment, two or more contact devices 10 can be simultaneously formed using a plurality of the integrated combinations.

Accordingly, for forming the integrated combination of the protruded portions 14 and the contact part 13, they can be formed on the plating portion 53 of the plating plate 51 by means of a plating method. Therefore, the plating plate 53 is properly placed on the plating plate 51 in place and formed with high accuracy. Furthermore, the distal end 11B of the coil spring 11 is mounted on the plating portion 53 to bind them with high accuracy. A positioning plate being stacked on the plating plate 51 may be used when the coil spring 11 is correctly positioned on the plating plate 53. In this case, the coil spring 11 is correctly positioned in a guiding hole formed on the positioning plate correctly, so that the coil spring 11 can be further correctly placed on the plating portion 53. By the way, if the contact part 13 is provided as a single component independently from other components, it becomes is difficult to handle the contact part 13 such a microscopic size part.

[Other preferred Embodiments]

The conical-shaped protruded portion 14 has been explained in the above description. According to the present invention, however, it is not limited to such a design. It may be alternatively formed as any one of various pyramid designs. For example, the protruded portion 14 may be in the shape of a rectangular pyramid. Also, three or more contact parts 13 may be provided on the plating plate 51.

Furthermore, a material to be used for preparing the contact part 13 and the protruded portion 14 is not limited to Ni. Any metal having the property of good plating may be selected form Cu, Fe, and so on. After performing the Au plating at first, Ni plating and so on may be performed. Also, plating metals of Ni and Cu may be piled.

Furthermore, a flat spring or the like may be used in stead of the coil spring 11.

The present invention has been described in detail with respect to preferred embodiments, and it will now be apparent from the foregoing to those skilled in the art that changes and modifications may be made without departing from the invention in its broader aspect, and it is the intention, therefore, in the apparent claims to cover all such changes and modifications as fall within the true spirit of the invention.

What is claimed is:

1. A contact device that is able to contact with a test terminal of a spherical type, comprising:
a spring; and
a contact part having one end on which two or more protruded portions are formed and the other end on which a top end of the sprig is attached, wherein
the protruded portions are able to contact with a spherical surface of the test terminal except for the top thereof.

2. A contact device as claimed in claim 1, wherein
the protruded portions are arranged about a center area of the contact part at intervals and forms a space between the center area of the contact part and the top of the spherical surface of the test terminal when the protruded portions are brought into contact with the spherical surface of the test terminal.

3. A contact device as claimed in claim 1, wherein
the protruded portions are concentrically arranged about the center area of the contact part at equal intervals.

4. A contact device as claimed in claim 1, wherein
the number of the protruded portions are at least three.

5. A contact device as claimed in claim 2, wherein
the spring is a coil spring having a spring axis coincident with an axis perpendicular to the center area of the contact part, and
a height of each protruded portion is defined by a formula of
h>r[1−{1−(a/r)²}^{1/2}]
wherein “h” denotes a height of each protruded portion and “r” denotes a radius of the test terminal, and “a” denotes a distance from the spring axis to the protruded portion.

6. A contact device as claimed in claim 1, wherein
the protruded port ions is substantially in the shape of a cone.

7. A contact device as claimed in claim 1, wherein
the contact part is attached on the top end of the spring after integrally making the contact part with the protruded portions by means of plating.

8. A method of making a contact device that is able to contact with a test terminal of a spherical type, comprising the steps of:
forming a contact part integrally with two or more protruded portions on one end of the contact part by means of plating, wherein the protruded portions are arranged so as to be able to contact with a spherical surface of the test terminal except for the top thereof; and
attaching the other end of the contact part with one end of a spring.

9. A method of making a contact device as claimed in claim 8, wherein
the contact part is formed on a plating plate, and then
the spring is attached on the contact part on the plating plate, followed by separating a combination of the contact part and the spring from the plating plate.
